(19) United States
(12) Patent Application Publication
(10) Pub. No.: US 2010/0123231 A1
(43) Pub. Date: May 20, 2010

(54) SEMICONDUCTOR DEVICE AND METHOD OF MANUFACTURING THE SAME

(75) Inventor: Kouhei TAKAHASHI, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/617,106

(22) Filed: Nov. 12, 2009

(30) Foreign Application Priority Data
Nov. 14, 2008 (JP) 2008-291757

(51) Int. Cl. H01L 23/495; H01L 21/60

(52) U.S. Cl. 257/676; 438/121; 257/E23.031; 257/E21.507

(57) ABSTRACT

A wiring board has a mounting region allowed for mounting of the semiconductor element, a solder layer is provided to the mounting region so as to bond the semiconductor element with the wiring board, and a divisional ridge which divides the solder layer into a plurality of regions in a plan view and surrounds the solder layer, is provided to the wiring board. A portion of the solder layer bonded to the semiconductor element has a thickness larger than the height of the divisional ridge.

This application is based on Japanese patent application No. 2008-291757 the content of which is incorporated hereinto by reference.

### BACKGROUND

1. Technical Field

The present invention relates to a semiconductor device and a method of manufacturing the same.

2. Related Art

Mounting of a semiconductor element such as power transistor, power IC or the like onto a wiring board such as lead frame, begins with formation of a solder layer on the wiring board. The semiconductor element is mounted on the solder layer, and the solder layer is then allowed to reflow, to thereby mount the semiconductor element on the wiring board.

In both processes of forming the solder layer on the wiring board, and of allowing the solder layer to reflow, the solder may occasionally wet and spread over the wiring board. If the solder excessively wets and spreads, the height of the solder layer may become non-uniform enough to cause variation in the state of connection between the semiconductor element and the wiring board.

For example, Japanese Published patent application A-H01-243439 discloses a method of providing ridge(s) on a lead frame, in order to keep a constant distance between the semiconductor element and the lead frame. According to this method, the semiconductor element may be supported by the ridge(s), so that the thickness of the solder may be kept constant, and thereby the solder may be controlled in the wettability and leakage. Japanese Published patent application A-H01-243439 discloses a ridge having a nearly cross pattern, and a set of a plurality of straight ridges aligned in parallel with each other.

Japanese Laid-open patent publication No. 2001-298033 and Japanese Published patent application A-H11-145363 disclose provision of a solder flow stopper on a lead frame. In each of these publications, the solder flow stopper is provided along the outer circumference of the mounting region of an electronic component.

In the technique described in Japanese Published patent application A-H01-243439, wetting and spreading of the solder fed onto the wiring board depend typically on material composing the wiring board, conditions of surface finishing (materials of plating, roughness, and so forth), and so forth. Accordingly, the solder may be anticipated to cause leakage from the region below the semiconductor element, and thereby to cause connection failure between the semiconductor element and the wiring board. On the other hand, the techniques described in Japanese Laid-Open Patent publication NOs. 2001-298033 and Japanese Published patent application A-H11-145363 may successfully suppress the solder from leaking out from the region below the semiconductor element, but may make the height of the solder layer non-uniform below the semiconductor element, to thereby incline the semiconductor element. As described in the above, it has been difficult to suppress any connection failure between the semiconductor element and the wiring board, and to suppress inclination of the semiconductor element.

### SUMMARY

According to the present invention, there is provided a semiconductor device which includes:

a semiconductor element;

a wiring board including a mounting region allowed for mounting of the semiconductor element;

a solder layer provided to the mounting region, aimed at bonding the semiconductor element and the wiring board; and

a divisional ridge provided to the wiring board, which divides the solder layer into a plurality of regions in a plan view and surrounds the solder layer,

wherein a portion of the solder layer bonded to the semiconductor element includes a thickness larger than the height of the divisional ridge.

According to the present invention, the wiring board is provided with the divisional ridge. Since the divisional ridge surrounds the solder layer, the solder may be suppressed from leaking from the mounting region. The portion of the solder layer bonded to the semiconductor element has a thickness larger than the height of the divisional ridge. By a synergistic operation of these factors, any connection failure between the semiconductor element and the wiring board may be suppressed. Since the divisional ridge divides the solder layer into a plurality of regions in a plan view, so that the solder layer may be prevented from causing non-uniformity in height due to maldistribution of the solder under the semiconductor element, and thereby the semiconductor element may be suppressed from inclining.

According to the present invention, there is provided also a method of manufacturing a semiconductor device, the method includes:

forming, over a wiring board including a mounting region allowed for mounting of the semiconductor element, a divisional ridge which divides the mounting region into a plurality of regions and surrounds the mounting region in a plan view;

forming a solder layer by feeding a solder to the mounting region surrounded by the divisional ridge, so as to make the thickness of the thickest portion of the solder layer larger than the height of the divisional ridge; and

mounting the semiconductor element on the wiring board, by placing the semiconductor element on the mounting region, and by allowing the solder to reflow.

According to the present invention, the semiconductor element and the wiring board may be suppressed from causing any connection failure therebetween, and the semiconductor element may be suppressed from inclining.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view illustrating a semiconductor device of a first embodiment;

FIG. 2 is a plan view of the semiconductor device illustrated in FIG. 1;

FIG. 3 is a plan view of a wiring board before being mounted with a semiconductor element;

FIGS. 4 to 6 are sectional views illustrating a method of manufacturing the semiconductor device;

FIG. 7 is an enlarged plan view of an essential portion of a wiring board used for a semiconductor device of a second embodiment;

FIG. 8A is a sectional view of a semiconductor device of a third embodiment, FIG. 8B is a plan view of the semiconductor device illustrated in FIG. 8A, and FIG. 8C is a plan view of a wiring board used for the semiconductor device illustrated in FIG. 8A;

FIG. 9A is a sectional view illustrating an exemplary mounting of a plurality of semiconductor elements on the wiring board illustrated in FIG. 8C, and FIG. 9B is a plan view of the semiconductor device illustrated in FIG. 9A;

FIG. 10A is a sectional view illustrating a semiconductor device of a fourth embodiment, FIG. 10B is a plan view of the semiconductor device illustrated in FIG. 10A, and FIG. 100 is a plan view of a wiring board used for the semiconductor device illustrated in FIG. 10A;

FIG. 11A is a sectional view illustrating an exemplary mounting of a semiconductor element different in size from the semiconductor element illustrated in FIGS. 10A and 10B on the wiring board illustrated in FIG. 10C, and FIG. 11B is a plan view of the semiconductor device illustrated in FIG. 11A; and

FIG. 12A is a sectional view of a semiconductor device of a fifth embodiment, FIG. 12B is a plan view of the semiconductor device illustrated in FIG. 12A, and FIG. 12C is a wiring board used for the semiconductor device illustrated in FIG. 12A.

### DETAILED DESCRIPTION

The invention will now be described herein with reference to an illustrative embodiment. Those skilled in the art will recognize that many alternative embodiments can be accomplished using the teachings of the present invention and that the invention is not limited to the embodiments illustrated for explanatory purposes.

Embodiments of the present invention will be explained referring to the attached drawings. Note that any similar constituents in all drawings will be given with similar reference numerals or symbols, and explanation therefor will not be repeated.

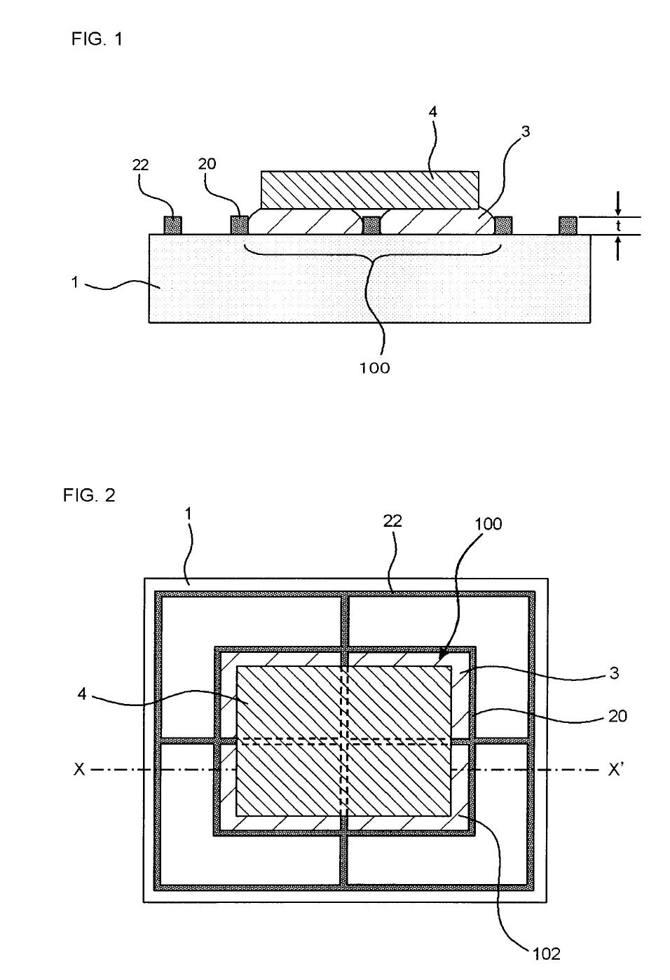

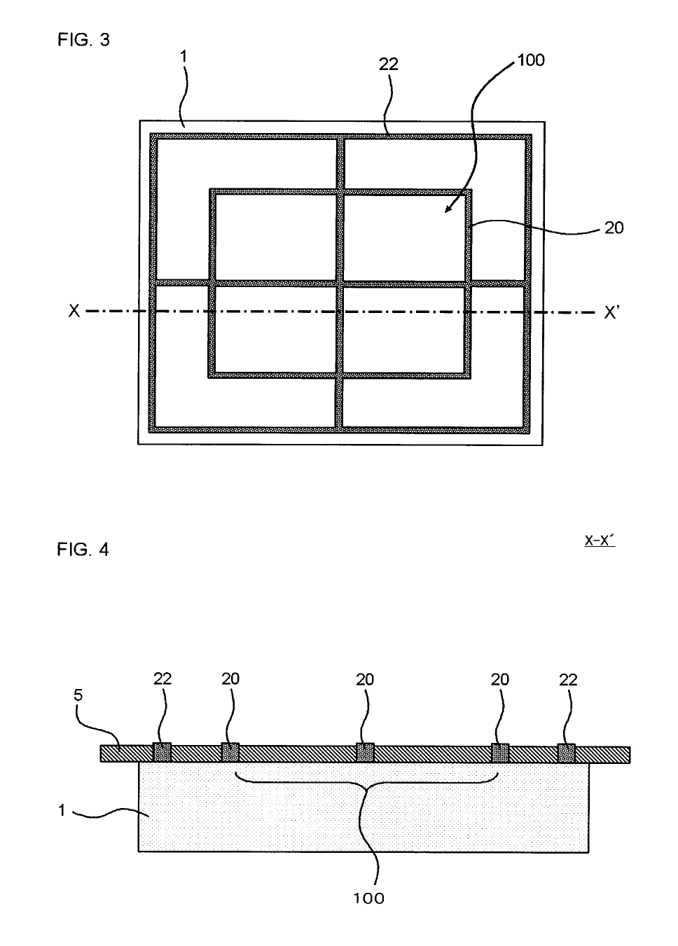

FIG. 1 is a sectional view illustrating a semiconductor device of a first embodiment, and FIG. 2 is a plan view of a semiconductor device illustrated in FIG. 1. FIG. 1 corresponds to a sectional view taken along line X-X′ in FIG. 2. FIG. 3 is a plan view of a wiring board 1 before being mounted with the semiconductor element. The semiconductor device has a wiring board 1, a divisional ridge 20, a solder layer 3, and a semiconductor element 4. The wiring board 1 has a mounting region 100 allowed for mounting of the semiconductor element 4. The solder layer 3 is provided to the mounting region 100, aimed at bonding the semiconductor element 4 with the wiring board 1. The divisional ridge 20 is provided to the wiring board 1, so as to divide the solder layer 3 into a plurality of regions in a plan view, and so as to surround the solder layer 3. A portion of the solder layer 3 bonded to the semiconductor element 4 has a thickness larger than the height of the divisional ridge 20. The semiconductor element 4 is a transistor or power IC, for example.

The wiring board 1 is a lead frame, for example. The divisional ridge 20 is formed using a material (polyimide resin, for example) which shows wettability to the solder layer 3 smaller than that shown by the wiring board 1. The height t of the divisional ridge 20 is determined based on a necessary thickness of the solder layer 3. The necessary thickness of the solder layer 3 is determined based on size of the semiconductor element 4, amount of heat generation, and thermal resistance. The height t of the divisional ridge 20 is typically equal to or larger than 10 μm and equal to or smaller than 100 μm.

The divisional ridge 20 has a pattern which is point-symmetrical around the center of the nearly-rectangular mounting region 100 allowed for mounting of the semiconductor element 4. The divisional ridge 20 exemplified in the drawing bisects the mounting region 100 respectively in the directions of longer edge and shorter edge, to thereby quadrisect the mounting region 100. More specifically, the divisional ridge 20 has an outer frame which surrounds the mounting region 100 and an nearly-cross inner frame which quadrisects the space inside the outer frame.

In the periphery around the divisional ridge 20, a second divisional ridge 22 is provided. The second divisional ridge 22 quadrisects the region outside the divisional ridge 20. The second divisional ridge 22 is used together with the divisional ridge 20, when the semiconductor element 4 is larger than that illustrated in FIG. 1 and FIG. 2. The geometries of the divisional ridge 20 and the second divisional ridge 22 are determined, depending on the geometry of the semiconductor element 4 to be mounted on the wiring board 1.

Next, a method of manufacturing the semiconductor device illustrated in FIG. 1 and FIG. 2, will be explained referring to sectional views illustrated in FIG. 4 to FIG. 6. First, as illustrated in FIG. 4, the divisional ridge 20 and the second divisional ridge 22 are formed on the wiring board 1 by screen printing. A mask 5 used herein for screen printing has an opening pattern corresponded to the divisional ridge 20 and the second divisional ridge 22.

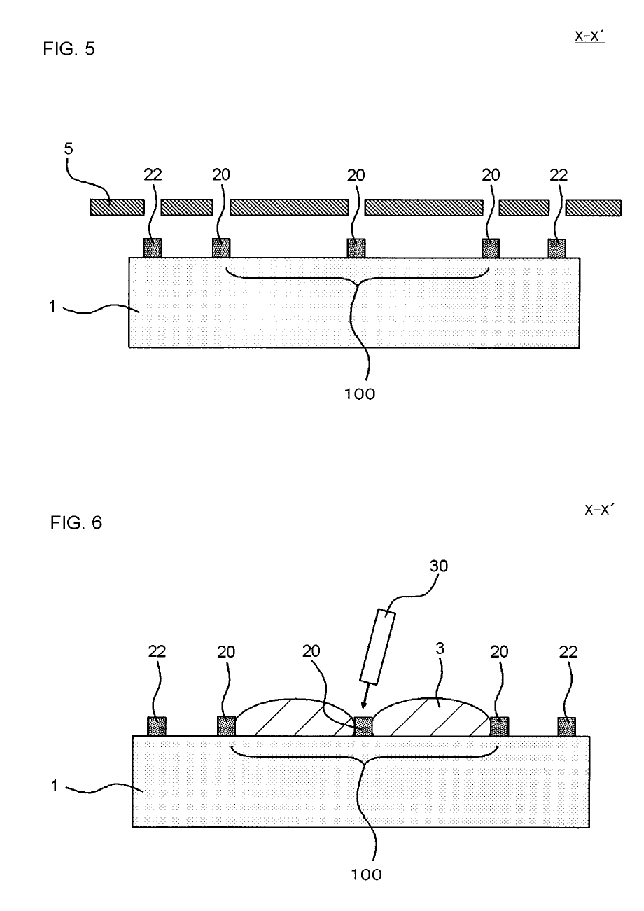

Thereafter, the mask 5 is removed from the wiring board 1 as illustrated in FIG. 5.

Next, as illustrated in FIG. 6, a solder is fed through a solder feed nozzle 30 onto the mounting region 100. The solder fed herein contains a flux, for example. The solder layer 3 is thus formed. In this embodiment, the solder layer 3 is divided into four regions by the divisional ridge 20. The thickness of the solder layer 3 is approximately equal in the individual regions. The amount of solder fed through the solder feed nozzle 30 is adjusted so as to make the thickness of the solder layer 3 larger than the height of the divisional ridge 20.

In this embodiment, the solder feed nozzle 30 is preferably positioned above the center portion of the cross-patterned inner frame of the divisional ridge 20. As described in the above, the divisional ridge 20 is formed using a material which shows wettability to the solder layer 3 smaller than that shown by the wiring board 1. As a consequence, the solder fed through the solder feed nozzle 30 is repelled by the divisional ridge 20, and nearly equally fed to each of the quadrisectioned regions of the mounting region 100. The thickness of the thickest portion of the solder layer 3 is made larger than the height of divisional ridge 20.

Thereafter, as illustrated in FIG. 1, the semiconductor element 4 is placed on the solder layer 3, and the solder layer 3 is allowed to reflow. The semiconductor element 4 is mounted on the wiring board 1 in this way. The semiconductor element 4 is bonded to each of the plurality of regions of the solder layer 3.

Alternatively, the solder for forming the solder layer 3 may not contain the flux. In this case, the semiconductor element 4 is mounted on the wiring board 1, by allowing the solder layer 3 to melt under a reductive atmosphere.

Next, operations and effects of this embodiment will be explained. According to this embodiment, the wiring board 1 is provided with the divisional ridge 20. The divisional ridge 20 surrounds the solder layer 3. The solder may therefore be suppressed from leaking from the mounting region 100. The portion of the solder layer 3 bonded to the semiconductor element 4 has a thickness larger than the height of the divisional ridge 20. By a synergistic operation of these factors, any connection failure between the semiconductor element 4 and the wiring board 1 may be suppressed. Since the divisional ridge 20 divides the solder layer 3 into a plurality of regions in a plan view, so that the solder layer 3 may be prevented from causing non-uniformity in thickness due to maldistribution of the solder under the semiconductor element 4, and thereby the semiconductor element 4 may be suppressed from inclining.

In addition, when the solder is fed through the solder feed nozzle 30 onto the mounting region 100 of the wiring board 1, the solder feed nozzle 30 is positioned above the center portion of the nearly cross-patterned inner frame of the divisional ridge 20. By virtue of this configuration, the solder may nearly equally be fed to each of the quadrisectioned regions of the mounting region 100, only by a single action of feeding of solder.

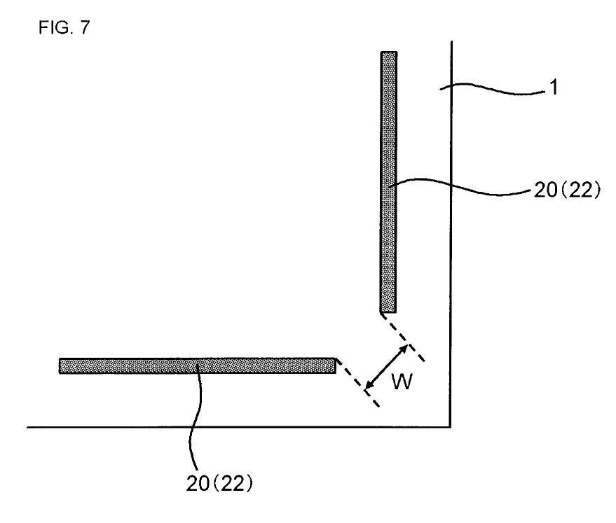

FIG. 7 is an enlarged plan view illustrating an essential portion of a wiring board 1 used for the semiconductor device of the second embodiment. The semiconductor device is configured similarly to the first embodiment, except that the divisional ridge 20 (or the second divisional ridge 22) on the wiring board 1 has a discontinuous portion. The width w of the discontinuous portion is set so that the solder may retain itself by the surface tension in the region surrounded by the divisional ridge 20, without causing leakage. The discontinuous portion of the divisional ridge 20 is typically provided to the corner.

Effects similar to those in the first embodiment may be obtained also by this embodiment.

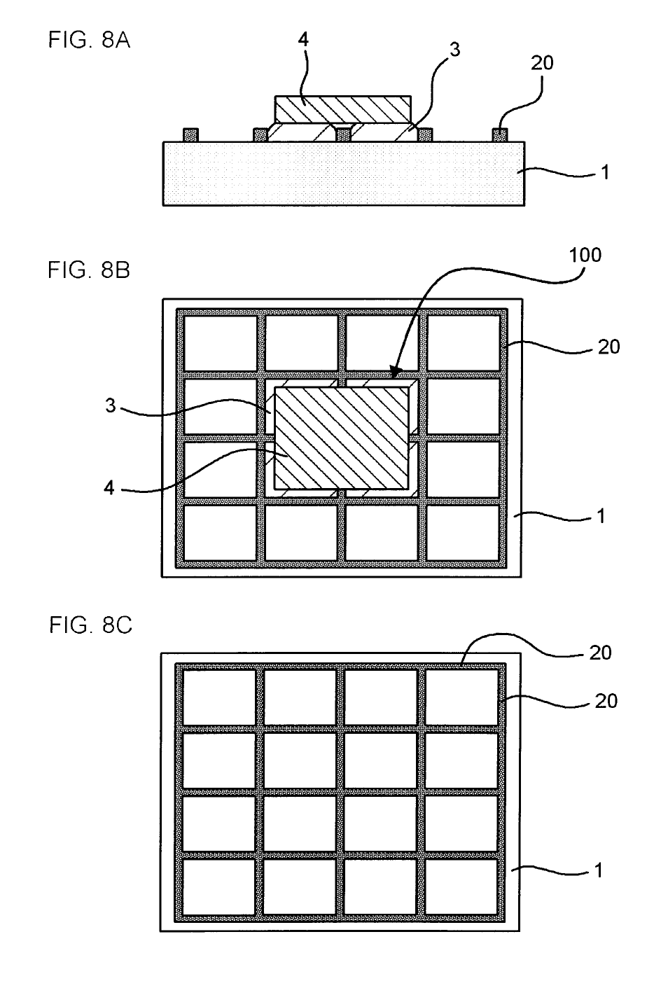

FIG. 8A is a sectional view of a semiconductor device of a third embodiment, and FIG. 8B is a plan view of the semiconductor device illustrated in FIG. 8A. FIG. 8C is a plan view illustrating the wiring board 1 used for the semiconductor device illustrated in FIG. 8A. The semiconductor device is similar to that of the first embodiment, except for the planar geometry of the divisional ridge 20 formed on the wiring board 1.

In the example illustrated in FIGS. 8A to 8C, the divisional ridge 20 is formed into a lattice pattern over the wiring board 1, and divides the mounting region 100 and the periphery therearound into at least 2×3 blocks. The mounting region 100 is composed of at least 2×2 blocks. For example, the divisional ridge 20 divides the mounting region 100 and the periphery therearound into 4×4 blocks, and the mounting region 100 is composed of 2×2 blocks.

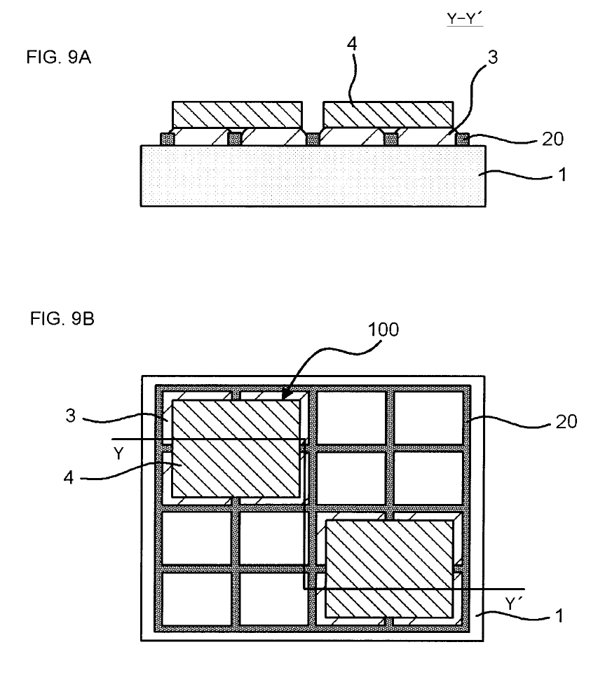

FIG. 9A is a sectional view illustrating an example having a plurality of semiconductor elements 4 mounted on the wiring board 1 illustrated in FIG. 8C, and FIG. 9B is a plan view corresponded to FIG. 9A. FIG. 9A is a sectional view taken along line Y-Y′ in FIG. 9B. As illustrated in FIGS. 9A and 9B, for the case where the divisional ridge 20 divides the wiring board 1 into 4×4 or more blocks, a plurality of mounting regions 100 may be set on the wiring board 1, and the semiconductor element 4 may be mounted on each of the mounting regions 100. In this case, the solder is fed independently to the mounting regions 100, and thereby the solder layer 3 may be formed independently from each other.

Effects similar to those in the first embodiment may be obtained also by this embodiment.

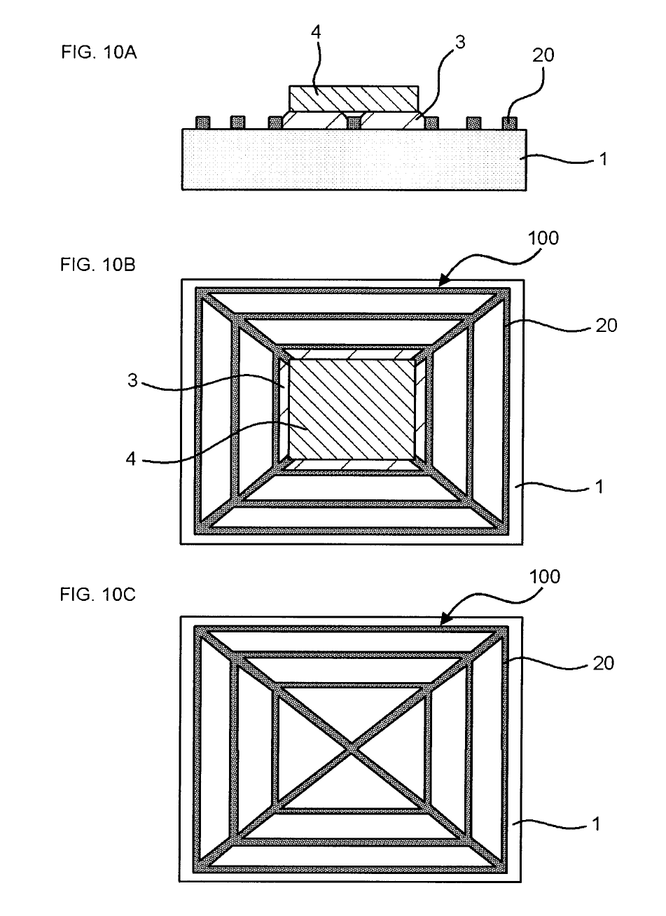

FIG. 10A is a sectional view illustrating a semiconductor device of a fourth embodiment, and FIG. 10B is a plan view of a semiconductor device illustrated in FIG. 10A. FIG. 10C is a plan view of a wiring board 1 used for the semiconductor device illustrated in FIG. 10A. The semiconductor device is similar to the semiconductor device of the first embodiment, except for the planar geometry of the divisional ridge 20 formed on the wiring board 1.

In this embodiment, the mounting region 100 of the wiring board 1 is allowed for mounting of any of plurality of types of semiconductor elements 4 which are similar but different in size. The divisional ridge 20 has radial (for example diagonal) portions which extend radially (for example diagonally) across the mounting region 100, and a plurality of frame portions respectively corresponded to the outer circumference of a plurality of semiconductor elements 4.

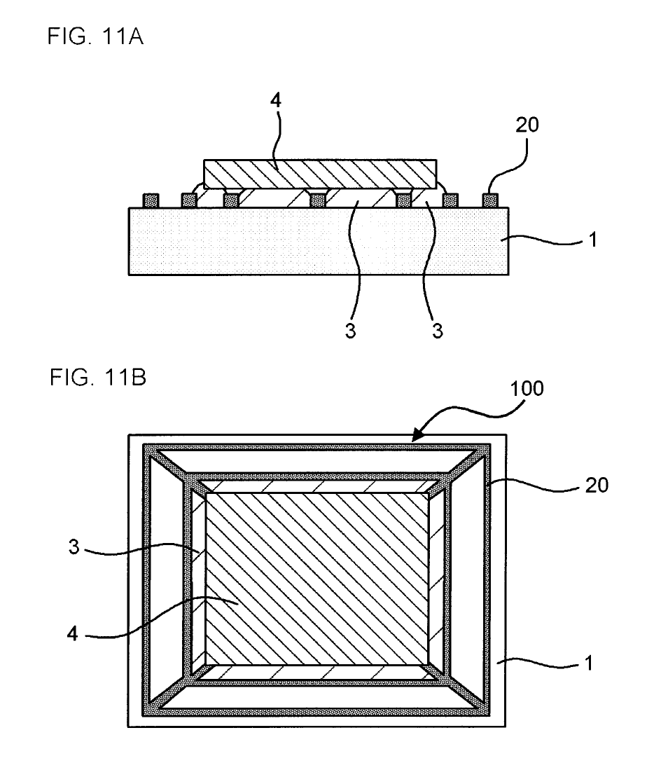

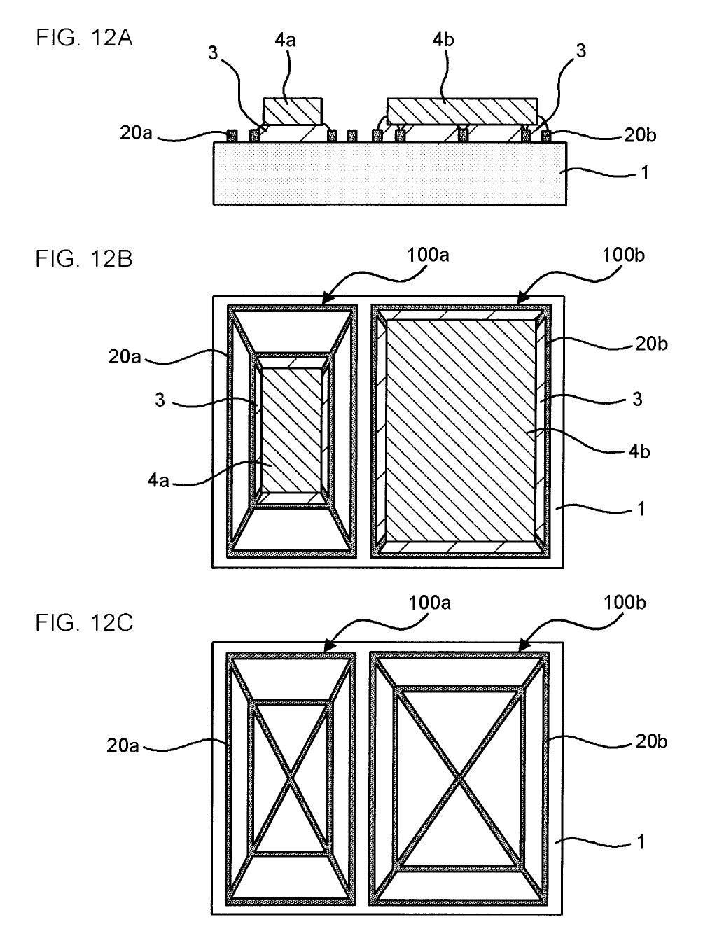

FIG. 11A is a sectional view illustrating an exemplary mounting of the semiconductor element 4 different in size from that illustrated in FIGS. 10A and 10B, on the wiring board 1 illustrated in FIG. 100, and FIG. 11B is a plan view corresponded to FIG. 11A. As illustrated in these drawings, any of plurality of types of semiconductor elements 4 which are similar but different in size may be mounted, by using the wiring board 1 illustrated in FIG. 100.

Effects similar to those in the first embodiment may be obtained also by this embodiment. In addition, any of plurality of types of semiconductor elements 4 which are similar but different in size may be mounted on a single type of wiring board 1.

FIG. 12A is a sectional view of a semiconductor device of a fifth embodiment, and FIG. 12B is a plan view of the semiconductor device illustrated in FIG. 12A. FIG. 12C is a plan view of the wiring board 1 used for the semiconductor device illustrated in FIG. 12A. The semiconductor device is similar to the semiconductor device of the fourth embodiment, except for the aspects below.

First, the wiring board 1 is provided with a mounting region 100a allowed for mounting of a semiconductor element 4a, and a mounting region 100b allowed for mounting of a semiconductor element 4b. The mounting region 100a has a divisional ridge 20a formed therein, and the mounting region 100b has a divisional ridge 20b formed therein. The divisional ridges 20a, 20b have radial (for example diagonal) portions which extend radially (for example diagonally) across the mounting regions 100a, 100b, and a plurality of frame portions respectively corresponded to the outer circumferences of the semiconductor elements 4a, 4b. Relation between the height of the divisional ridges 20a, 20b and the thickness of the solder layer 3 is similar to the relation between the height of the divisional ridge 20 and the thickness of the solder layer 3 in the first embodiment.

Effects similar to those in the first embodiment may be obtained also in this embodiment. A plurality of semiconductor elements 4a, 4b may be mounted. In addition, any of plurality of types of semiconductor elements 4a which are similar but different in size, and any of plurality of types of semiconductor elements 4b which are similar but different in size, may be mounted on a single type of wiring board 1.

The embodiments of the present invention have been described in the above referring to the attached drawings, merely as examples of the present invention, without being precluded from adoption of any other various configurations.

It is apparent that the present invention is not limited to the above embodiments, but may be modified and changed without departing from the scope and spirit of the invention.

What is claimed is:

1. A semiconductor device comprising:
a semiconductor element;
a wiring board including a mounting region allowed for mounting of said semiconductor element;
a solder layer provided to said mounting region, aimed at bonding said semiconductor element and said wiring board; and
a divisional ridge provided to said wiring board, which divides said solder layer into a plurality of regions in a plan view and surrounds said solder layer,
wherein a portion of said solder layer bonded to said semiconductor element includes a thickness larger than the height of said divisional ridge.

2. The semiconductor device as claimed in claim 1,
wherein said wiring board is a lead frame.

3. The semiconductor device as claimed in claim 1,
wherein said divisional ridge is composed of a polyimide resin.

4. The semiconductor device as claimed in claim 1,
wherein said divisional ridge partially includes a discontinuous portion.

5. The semiconductor device as claimed in claim 1,
wherein said divisional ridge is formed into a lattice pattern over said mounting region and the periphery around said mounting region over said wiring board, while dividing said mounting region and the periphery around said mounting region into at least 2×3 blocks, and
said mounting region is composed of at least 2×2 blocks of said blocks.

6. A method of manufacturing a semiconductor device comprising:
forming, over a wiring board including a mounting region allowed for mounting of said semiconductor element, a divisional ridge which divides said mounting region into a plurality of regions and surrounds said mounting region in a plan view;
forming a solder layer by feeding a solder to said mounting region surrounded by said divisional ridge, so as to make the thickness of the thickest portion of said solder layer larger than the height of said divisional ridge; and
mounting said semiconductor element on said wiring board, by placing said semiconductor element on said mounting region, and by allowing said solder to reflow.

7. The method of manufacturing a semiconductor device as claimed in claim 6,
wherein said forming said divisional ridge is a process of forming said divisional ridge by screen printing.
